(19) United States
(12) Patent Application Publication
(10) Pub. No.: US 2006/0082252 A1
(43) Pub. Date: Apr. 20, 2006

(54) Method for determining the position of a movable shut-off element of an injection valve

(75) Inventors: Klaus Allmendinger, Bachhagel (DE); Tobias Flaemig-Vetter, Esslingen (DE); Michael Froehlich, Esslingen (DE); Zandra Jansson, Esslingen (DE); Stefan Knedlik, Siegen (DE); Kai Koenig, Bergneustadt (DE); Otmar Loffeld, Wilnsdorf (DE); Dirk Mehlfeldt, Esslingen (DE); Holger Nies, Netphen (DE); Valerij Peters, Siegen (DE); Guenter Stoehr, Neuhausen (DE)

Correspondence Address: CROWELL & MORING LLP;INTELLECTUAL PROPERTY GROUP, P.O. BOX 14300, WASHINGTON, DC, 20044-4300, US

(73) Assignee: DaimlerChrysler AG, Stuttgart (DE)

(21) Appl. No.: 11/127,158

(22) Filed: May 12, 2005

(30) Foreign Application Priority Data
May 13, 2004 (DE) 10 2004 023 545.7

(51) Int. Cl. H01L 41/04; H02N 2/00

(52) U.S. Cl. 310/316.03

(57) ABSTRACT

A method for determining the position of a movable shut-off element, in particular a valve needle, of an injection valve in a motor vehicle engine. The shut-off element is driven by means of a piezo element for the opening or closing of the injection valve. A voltage signal assigned to an electrical voltage detected at the piezo element is determined and used for determining the position of the shut-off element. By means of a model, a modelled variation of the voltage is determined and is likewise used for determining the position of the shut-off element. In particular, the determination of the position of the shut-off element takes place by using the difference from the modelled variation of the voltage and the determined voltage signal.

This application claims the priority of German Patent Document No. 10 2004 023 545.7, filed May 13, 2004, the disclosure of which is expressly incorporated by reference herein.

### BACKGROUND AND SUMMARY OF THE INVENTION

The invention relates to a method for determining the position of a movable shut-off element of an injection valve in a motor vehicle engine.

For supplying fuel to internal combustion engines, common-rail systems operating under very high injection pressures are used. These injection systems are distinguished by the fact that the fuel is pumped by a high-pressure pump into a pressure accumulator assigned jointly to all the cylinders of the engine, from which the injection valves at the individual cylinders are supplied. The injection valves are often also known as injectors. The opening and closing of the injection valves is usually electrically controlled, for example with the aid of piezo elements as actuators.

In the case of injection valves or injectors, it is possible to switch a control valve as a shut-off element between the nozzle body with the nozzle needle, which opens and closes the injection holes in the injection valve, and the piezoelectric actuator. The control valve serves the purpose of hydraulically effecting the opening and closing of the actual fuel injection valve, that is to say in particular fixing the exact timing of the beginning and end of the injection operation. The injection valve is intended for example to open in a controlled manner and to close rapidly at the end of the injection operation. The injection of extremely small amounts of fuel for pre-injection prior to the actual injection is also intended to be possible, allowing the combustion process to be optimized. The shut-off element may, however, also be arranged in a different form and at a different point of the injection valve, for example as a valve flap or needle valve at the valve outlet. An injector needle may be used in particular as the shut-off element. The injection valve may be formed as a needle valve.

DE 199 60 971 A1 discloses arranging a piezo element used as an actuator in the form of a piezo stack, which is provided for performing an electrically controlled mechanical lifting movement, in series with a second piezo element, in order to use the second piezo element as a sensor element for the lifting movement of the first, actuating piezo element. Such an arrangement may be used to determine the position of a component that is driven by the actuating piezo element. An injector for injecting fuel into the combustion space of a motor vehicle is known from the cited laid-open patent application as one possible application for such an arrangement.

DE 199 30 309 C2 discloses a method for controlling a fuel injection operation with a fuel injection valve for an internal combustion engine of a motor vehicle. For opening the injection valve, a control valve as a shut-off element is actuated by a piezo element as an actuator. For changing the state of the shut-off element, the piezo element is electrically activated. After this activation, the voltage at the piezo element is measured and the measured voltage is used to determine the beginning of injection or the needle opening time of the injection valve.

It is the object of the invention to permit a simple, exact and rapid determination of the position of a shut-off element of an injection valve in a motor vehicle engine.

In the case of the method according to the invention, a shut-off element of an injection valve is driven by means of a piezo element provided as an actuator for the opening or closing of the injection valve. An individual piezo element or an arrangement of individual piezo elements, for example a piezo stack, may be used here as the piezo element. An electrical voltage is detected at the piezo element. A voltage signal assigned to the detected voltage is determined. The voltage signal is used for determining the position of the shut-off element. By means of a model, a modelled variation of the voltage is determined and used for determining the position of the shut-off element. An equivalent circuit diagram of the piezo element or an electric circuit comprising the piezo element, for example the piezo element and its electrical leads, may be used as a basis for the model. The model is preferably an algorithm which describes a predeterminable idealized behaviour of the modelled piezo element. However, an equivalent physical unit may also be used as the model. A comparison of the variation of the voltage modelled by means of the model with the variation of the voltage determined by measurement makes it possible to obtain a good determination of the position of the shut-off element.

The method described has the advantage that the position of a shut-off element of an injection valve can be reliably determined without an additional sensor. In particular, the position of the shut-off element can be determined without providing a specific position-detecting mode of the injection valve and putting the shut-off means or actuator actuating the shut-off means into this position-detecting mode.

In a refinement of the method for determining the position of a movable shut-off element of an injection valve, a differential voltage u_{Diff}(t) is determined by determining the difference from the determined voltage signal uₚ(t) and the modelled variation of the voltage uᵢ(t) and using it to determine the position of the shut-off element. The algebraic sign of the difference is of secondary importance here, so that it is insignificant which value is subtracted from the other.

In a further refinement, an extreme value of the differential voltage u_{Diff}(t) is assigned a predeterminable position of the shut-off element. In particular, the predeterminable position of the shut-off element correlates with the beginning or the end of an injection operation. Regarded here as the local extreme value of the differential voltage u_{Diff}(t) in a broader sense are all extreme values which correspondingly satisfy predeterminable criteria with regard to the amount, the algebraic sign, the curvature, smoothness of the curve, etc. The determination of a local extreme value of the differential voltage represents a reliable and easily implementable evaluation of the determined curve, to allow a defined position of the shut-off element to be deduced. Based on the knowledge of a defined position of the shut-off element at a defined point in time, it is possible in the further course of events over time for the time-dependent position of the shut-off element to be determined particularly accurately and reliably.

In a refinement of the method which produces particularly reliable results, a Fourier transformation of the differential voltage u_{Diff}(t) is carried out to reduce the measurement noise. Using the Fourier transform F(u_{Diff}(t)) of the differential voltage, the fundamental wave of an energy density spectrum assigned to the voltage signal is determined. This fundamental wave is at least largely free from superimposed disturbances, in particular measurement noise, and this fundamental wave is therefore reliable and easy to evaluate.

A further preferred possibility for evaluation is obtained by determining the modelled voltage uᵢ(t) as the integration over time of the piezo current iᵢ divided by a capacitance C modelling the piezo stack. The level of the capacitance C can be determined here by a comparison of a voltage signal determined under predeterminable conditions with a modelled variation of the voltage.

In a further refinement of the method for determining the position of a movable shut-off element of an injection valve, the piezo element for controlling the shut-off device of the injection valve is driven by means of a current controller. The shut-off device of the injection valve is controlled by predetermining the current flowing through the piezo element. To determine the position of the shut-off element, the electrical voltage at the piezo element is detected and evaluated. As an alternative to detecting the piezo voltage during a current-supplying operation, the detection of the piezo voltage may also take place during periods when current is not being supplied. For this purpose, the piezo element may be electrically disconnected from the current supply during periods when current is not being supplied, so that detection of the piezo voltage is possible on the piezo element while it is electrically free.

The determination of the position of the shut-off element is preferably used for controlling the variation of the injection of an injection valve. Controlling the variation of the injection may take place to reduce the fuel consumption, lower harmful emissions or, for example, optimize engine noise.

The shut-off element of the injection valve may be any desired shut-off element, such as for example a flap, but a longitudinally displaceable injector needle is used with preference.

A particularly advantageous application of the method is obtained in measuring the needle position of an injector needle in an injection injector that is driven by means of a piezo element. With respect to their dynamic behaviour, piezo actuators make high actuating forces and short response times possible in narrow injection profiles, such as the pre-injection and post-injection for reducing the noise development and the harmful substances during the combustion sequence. Exact knowledge of the position of the injector needle is particularly advantageous here with respect to the camshaft adjustment for injection time periods less than 100 μs.

Other objects, advantages and novel features of the present invention will become apparent from the following detailed description of the invention when considered in conjunction with the accompanying drawings.

### BRIEF DESCRIPTION OF THE DRAWINGS

FIG. 1 shows a qualitative representation of measured variations over time of characteristic variables of a fuel injection injector: variation of the amount injected 3, variation of the piezo voltage 4, variation of the fuel pressure 2 and variation of the piezo current 5,

FIG. 2 shows a block diagram of a unit for determining the differential voltage from the measured variation of the voltage 4 and the modelled variation of the voltage 7 at the piezo element,

FIG. 3 shows a measured variation 4 over time and a modelled variation 7 over time of a piezo voltage with the determined beginning of injection t_{A} and end of injection t_{E}.

### DETAILED DESCRIPTION OF THE DRAWINGS

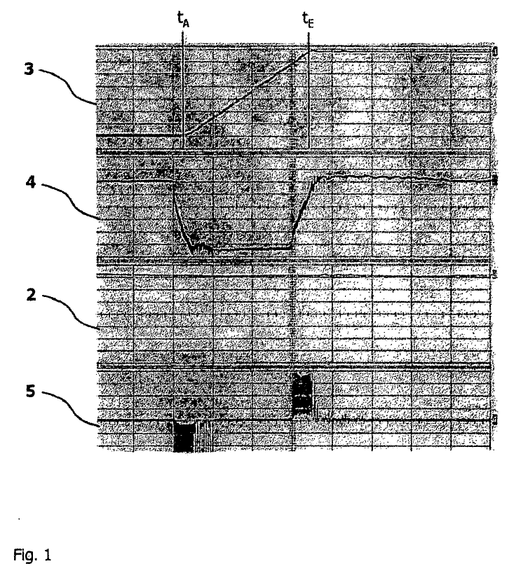

FIG. 1 shows the variation of various characteristic variables of an injection injector when the original stack length L of the actuator changes by the change in length ΔL. The actuator comprises electrically contacted piezo sheets or elements stacked one on top of the other. The change in length of the actuator is transmitted to the injector needle, in order to inject the fuel under pressure in a controlled manner into a target space in a way corresponding to the size of the change in length and the time duration of the change in length. Targeted activation of the piezo actuator has the effect of generating a specific profile of the variation of the amount injected 3 and, as a measurable volume V(t) of the amount of fuel injected in relation to a defined time window from the beginning t_{A} to the end t_{E} by means of the injector.

On the basis of the current feeding, the current signal 5 and the mechanical reaction of the injector needle are reflected in the variation over time of the voltage signal 4 of the measured piezo voltage uₚ(t), so that the beginning of injection t_{A} and the end of injection t_{E} can be detected from the voltage signal uₚ(t). Detection of the points in time t_{E} and t_{A}, and consequently in particular of the position of the injector needle, is made possible by the electrical input variable iₚ(t) being separated from the reactive forces F(t) of the injector needle during the injection operations. Such a separation may take place by means of forming the difference between a modelled variation of the voltage and the variation of the voltage measured at a piezo element.

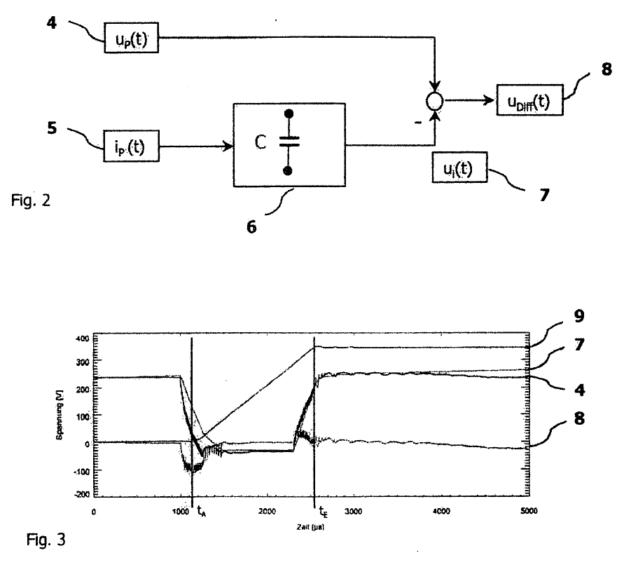

For the modelling, the capacitance C of the piezo element in particular is singled out from the equivalent circuit diagram of a stack comprising n piezo elements, according to the block circuit diagram in FIG. 2, and viewed in isolation. By means of this capacitance C, the modelled piezo voltage in block 7 is determined in block 6 using the measured piezo current iₚ(t) from block 5. The associated variation of the voltage uᵢ(t) modelled in this way can be calculated from the integral relationship uᵢ=1/C·∫iᵢ dt. This modelled variation of the voltage is compared with the measured variation of the voltage uₚ(t) from block 4, in particular the differential voltage determined in block 8.

The determination of the capacitance C of the piezo stack preferably takes place by adapting the amplitude of the modelled variation of the voltage uᵢ(t) to the measured actual variation of the voltage uₚ(t). In the case of the piezo elements of the injectors investigated, capacitance values of around 10 μF were found.

A comparison of the variation 4 of the measured voltage uₚ(t) with the variation 7 of the modelled voltage uᵢ(t) according to FIG. 3 leads to the variation 8 over time of the differential voltage u_{Diff}(t)=uₚ(t)−uᵢ(t). It is evident from this that the beginning of injection t_{A} coincides with the first local minimum and the end of injection t_{E} coincides with the second local minimum in the variation of the differential voltage. Additionally indicated as a reference curve is the variation of the amount injected 9.

To improve the assignment of characteristic points of the differential voltage and characteristic points of the variation of the amount injected, in an advantageous development of the method a Fourier transformation of the original variation over time of the differential voltage u_{Diff}(t) is carried out with U_{Diff}(f)=Φ{u_{Diff}(t)}. By means of a calculation of the fundamental wave of the energy density spectrum H(f)=|U_{Diff}(f)|² in the determination of the position of an injector needle from the first two local minima of H(f), the method according to the invention is additionally improved, since the first minima of the fundamental wave correlate particularly strongly with the points in time of the beginning of injection and the end of injection, and therefore with the position of a shut-off element of an injection valve, in particular an injector needle, and the portion of the energy density spectrum made up by the fundamental wave follows a particularly smooth variation, and can therefore be evaluated easily and reliably.

One advantageous possibility for determining the position of a movable shut-off element of an injection valve is the determination of the differential voltage (8) u_{Diff}(t) by means of a Kalman filter. This involves subtracting a measured value of the piezo voltage from a voltage value modelled by means of a Kalman filter, the so-called prediction value, in order to determine the remainder res(t). This remainder res(t) is used for determining the position of the injection valve, it being possible for the evaluation of the remainder to take place in the same way as the evaluation of the differential voltage. The piezo current is incorporated in the method as the deterministic controlled variable.

The determination of the position of the injection needle by means of a Kalman filter can be extended by also determining at the same time further variables, such as for example the capacitance of the piezo element, during the opening or closing operation. Selected variables or all the variables determined by means of this approach may form the state vector here. The observed variable incorporated in the method is the measured piezo voltage, the number of observation values N preferably being chosen such that this number is less than the number of the states to be determined, since otherwise on the one hand the increase in information is only small and on the other hand the time required for carrying out the method increases.

1. A method for determining the position of a movable shut-off element of an injection valve in a motor vehicle engine,
the shut-off element being driven by means of a piezo element for the opening or closing of the injection valve, and
a voltage signal assigned to an electric voltage detected at the piezo element being determined, and
the voltage signal being used for determining the position of the shut-off element,
wherein, by means of a model, a modelled variation of the voltage is determined and used for determining the position of the shut-off element.

2. A method according to claim 1, wherein a differential voltage u_{Diff}(t) is determined by forming the difference from the determined voltage signal uₚ(t) and the modelled variation of the voltage uᵢ(t) and is used for determining the position of the shut-off element.

3. A method according to claim 2, wherein a local extreme value of the differential voltage u_{Diff}(t) is assigned a predeterminable position of the shut-off element.

4. A method according to claim 3, wherein the predeterminable position of the shut-off element is correlated with the beginning or the end of an injection operation.

5. A method according to claim 2, wherein a Fourier transformation is carried out with the differential voltage u_{Diff}(t) to reduce the measurement noise and the fundamental wave of an energy density spectrum assigned to the voltage signal is determined by means of the Fourier transform F(u_{Diff}(t)) of the differential voltage u_{Diff}(t).

6. A method according to claim 1, wherein the modelled voltage uᵢ(t) is formed as the integration over time of the piezo current ii divided by a capacitance C modelling the piezo stack.

7. A method according to claim 6, wherein the level of the capacitance C is determined by a comparison of a voltage signal determined under predeterminable conditions with a modelled variation of the voltage.

8. A method according to claim 1, wherein the piezo element for controlling the shut-off device of the injection valve is driven by means of a current controller.

9. A method according to claim 1, wherein the determination of the position of the shut-off element is used for controlling the variation of the injection.

10. A method according to claim 1, wherein the shut-off element is a longitudinally displaceable injector needle.

11. A method for determining the position of a movable shut-off element of an injection valve in a motor vehicle engine, comprising
driving the shut-off element using a piezo element for opening or closing the injection valve;
detecting a voltage signal from the piezo element;
using the voltage signal to determine the position of the shut-off element; and
using a model to determine a modelled variation of the voltage; and
using the determined modelled variation of the voltage to determine the position of the shut-off element.

12. A method according to claim 11, further comprising:
determining a differential voltage u_{Diff}(t) from a difference between the determined voltage signal uₚ(t) and the modelled variation of the voltage uᵢ(t); and
using the differential voltage U_{Diff}(t) to determine the position of the shut-off element.

13. A method according to claim 12, further comprising assigning a predeterminable position of the shut-off element to a local extreme value of the differential voltage U_{Diff}(t).

14. A method according to claim 13, further comprising correlating the predeterminable position of the shut-off element with the beginning or the end of an injection operation.

15. A method according to claim 12, further comprising:
carrying out a Fourier transformation with the differential voltage u_{Diff}(t) to reduce the measurement noise; and
determining the fundamental wave of an energy density spectrum assigned to the voltage signal by way of the Fourier transform F(u_{Diff}(t)) of the differential voltage u_{Diff}(t).

16. A method according to claim 11, further comprising forming the modelled voltage uᵢ(t) as the integration over time of the piezo current iᵢ divided by a capacitance C modelling the piezo stack.

17. A method according to claim 16, further comprising determining the level of the capacitance C by a comparison of a voltage signal determined under predeterminable conditions with a modelled variation of the voltage.

18. A method according to claim 11, further comprising driving the piezo element for controlling the shut-off device of the injection valve by way of a current controller.

19. A method according to claim 11, further comprising using the determination of the position of the shut-off element for controlling the variation of the injection.

20. A method according to claim 11, wherein the shut-off element is a longitudinally displaceable injector needle.
